(19) United States
(12) Patent Application Publication
(10) Pub. No.: US 2018/0081276 A1
(43) Pub. Date: Mar. 22, 2018

(54) PHOTORESIST AND ETCHING METHOD

(71) Applicant: BOE TECHNOLOGY GROUP CO., LTD., Beijing (CN)

(72) Inventor: Shantao CHEN, Beijing (CN)

(73) Assignee: BOE TECHNOLOGY GROUP CO., LTD., Beijing (CN)

(21) Appl. No.: 15/678,711

(22) Filed: Aug. 16, 2017

(30) Foreign Application Priority Data
Sep. 22, 2016 (CN) 201610843209.3

(51) Int. Cl. G03F 7/20; G03F 7/16; G03F 7/004

(52) U.S. Cl. CPC G03F 7/2043; G03F 7/16; H01L 21/0274; G03F 7/2004; G03F 7/0045

(57) ABSTRACT

The present disclosure discloses a photoresist including an ionizable substance capable of being ionized to generate ions under irradiation of UV light, and an etching method using the photoresist.

### CROSS-REFERENCE TO RELATED APPLICATION

This application claims priority to Chinese Patent Application No. 201610843209.3 filed on Sep. 22, 2016, which is incorporated herein by reference in its entirety.

### TECHNICAL FIELD

The present disclosure relates to the field of display technology, and in particular to a photoresist and an etching method.

### BACKGROUND

At present, the display technology has been widely used for televisions, mobile phones and the display of public information. A display product for displaying images mainly includes an array substrate for driving a display panel to display the images and a color filter substrate for achieving color display. However, since in the process of manufacturing the array substrate and the color filter substrate, densities of patterns in different regions on the substrate are different and this difference will cause amounts of ions consumed in these regions during etching to be different, etching rates will be different in these regions and a problem of poor etching uniformity may occur accordingly. Specifically, ions will be consumed during the etching. A large number of ions are consumed in a densely-patterned region, while a small number of ions are consumed in a non-densely-patterned region; therefore, the different densities of patterns in the different regions lead to different consumption degrees of the ions in these regions. Accordingly, the ionic concentration varies with the region, which is likely to result in different etching rates in different regions and thus poor etching uniformity on the substrate.

How to improve the etching uniformity in the manufacturing process of a display panel is a technical problem that needs to be solved in the art.

### SUMMARY

In order to solve the above problem, the present disclosure provides in embodiments a photoresist and an etching method.

The present disclosure provides in an embodiment a photoresist which includes an ionizable substance capable of being ionized to generate ions under the irradiation of ultraviolet (UV) light.

In an optional embodiment, the ionizable substance in the photoresist provided in the present disclosure includes chlorobenzenes.

In an optional embodiment, the photoresist is used for wet-etching.

The present disclosure further provides in an embodiment an etching method using the photoresist as described above, which includes: coating the photoresist on a film layer to be etched on a base substrate, wherein the photoresist includes an ionizable substance capable of being ionized to generate ions under the irradiation of UV light; exposing the base substrate coated with the photoresist to the UV light using a mask plate; wet-etching the exposed base substrate using an etching solution; and removing the remaining photoresist.

In an optional embodiment, the ionizable substance includes chlorobenzenes.

In an optional embodiment, the method further includes providing the UV light through a high-pressure mercury lamp.

In an optional embodiment, the UV light in the etching method is provided at a wavelength of 254 nm, light intensity of 180 μW/cm², and a dose of 160 mJ/cm².

In an optional embodiment, a molar extinction coefficient of the chlorobenzenes is 139.6 M⁻¹cm⁻¹.

The embodiments of the present disclosure produce at least the following advantageous effects. According to the photoresist and the etching method provided in the present disclosure, the photoresist includes the ionizable substance capable of being ionized to generate ions under the irradiation of UV light. By adding such an ionizable substance to the photoresist, ions may be generated by the ionizable substance under the action of UV light during the etching. A force of attraction among electric charges accelerates the movement of the ions such that the ionic concentrations in different regions are balanced. Thus, it is able to timely replenish the ions consumed in each region on the substrate which is being etched, especially in the densely patterned region, thereby achieving the balance of the etching rates in different regions and ensuring the etching uniformity of the entire substrate.

### BRIEF DESCRIPTION OF THE DRAWINGS

FIG. 1 is a schematic view of ionization of chlorobenzene according to an embodiment of the present disclosure;

FIG. 2 is a flowchart of an etching method according to an embodiment of the present disclosure;

FIG. 3 is a schematic view of the distribution of ionic concentrations according to an embodiment of the present disclosure;

FIG. 4 is a graph of the relationship between a concentration of chlorobenzene and a dose of UV light according to an embodiment of the present disclosure; and

FIG. 5 is a graph showing the change in the reaction rate of chlorobenzene over time according to an embodiment of the present disclosure.

### DETAILED DESCRIPTION

Specific embodiments of the photoresist and the etching method according to the present disclosure will be described hereinafter in detail in conjunction with the accompanying drawings.

The present disclosure provides in an embodiment a photoresist including an ionizable substance capable of being ionized to generate ions under the irradiation of UV light. By adding such an ionizable substance to the photoresist, ions are generated by the ionizable substance under the action of UV light during the etching. A force of attraction between electric charges accelerates the movement of the ions such that the ionic concentrations in different regions are balanced. Thus, it is able to timely replenish the ions consumed in each region on the substrate which is being etched, especially in the densely patterned region, thereby achieving the balance of the etching rates in different regions and ensuring the etching uniformity of the entire substrate.

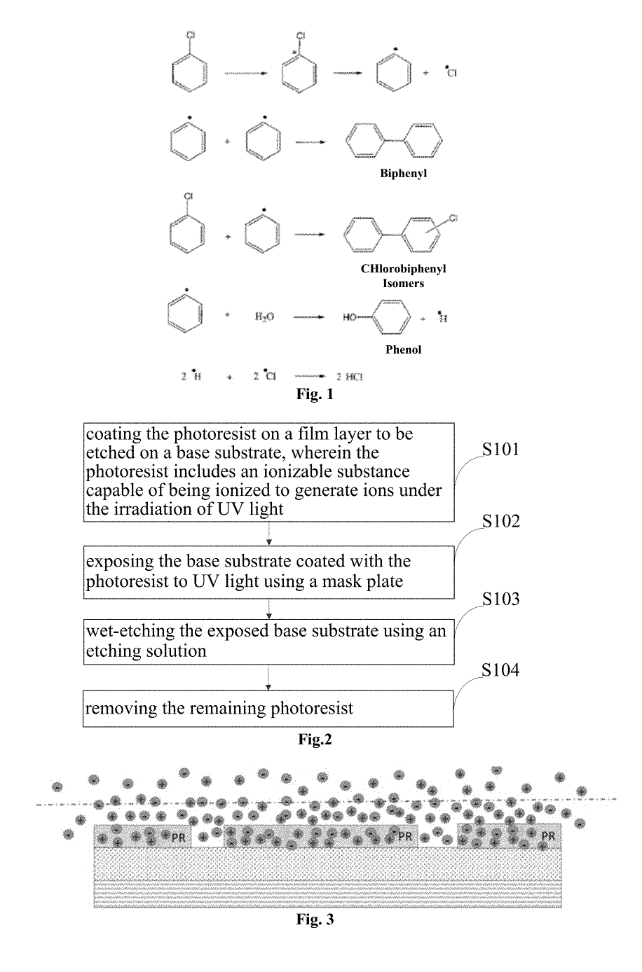

According to the embodiment of the present disclosure, the ionizable substance may include chlorobenzenes. As shown in FIG. 1, chlorobenzene may be ionized to generate ions under the irradiation of UV light, that is, after a chlorobenzene molecule absorbs photons, a photo chemical reaction occurs to yield other products (such as benzene, biphenyl, chlorobiphenyl isomers, phenol) and ions. In other words, the chlorobenzene molecule is excited under the irradiation of UV light, and a speed of excitation depends on the concentration and extinction coefficient of chlorobenzene at the wavelength of the UV light. The chlorobenzene molecule in the excited state undergoes an exothermic reaction or photodecomposition reaction to form an intermediate product which may further absorb photons to become an excited intermediate and be further decomposed.

According to the embodiment of the present disclosure, the photoresist may be used for wet-etching. Specifically, a solution of chlorobenzene with a certain concentration is added to the photoresist, and by carrying out the exposure and development under UV light during the etching, chlorobenzene may be ionized to generate ions during the exposure to replenish ions that are consumed during the etching. Thus, a balance of the etching rates in different regions is kept and the etching uniformity of the entire substrate can be ensured.

Based on the same inventive concept, the present disclosure provides in an embodiment an etching method using the photoresist as provided above in the present disclosure, which, as shown in FIG. 2, may include: S101: coating the photoresist on a film layer to be etched on a base substrate, wherein the photoresist includes an ionizable substance capable of being ionized to generate ions under irradiation of UV light; S102: exposing the base substrate coated with the photoresist to UV light using a mask plate; S103: wet-etching the exposed base substrate using an etching solution; and S104: removing the remaining photoresist.

In the etching method according to the embodiment of the present disclosure, the photoresist including the ionizable substance is used for etching. By carrying out the exposure under UV light during the etching, the ionizable substance may be ionized to generate ions. A force of attraction between electric charges accelerates the movement of the ions such that the ionic concentrations in different regions are balanced. Thus, it is able to timely replenish the ions consumed in each region on the substrate which is being etched, especially in the densely patterned region, thereby achieving the balance of the etching rates in different regions and ensuring the etching uniformity of the entire substrate.

Specifically, during the exposure, chlorobenzenes in the photoresist may be ionized to generate ions under the UV light emitted from a high pressure mercury lamp so that a condition for subsequently accelerating the movement of the ions is provided. In general, after entering the etching process, densities of patterns in different regions on the substrate are different and this difference will cause amounts of ions consumed in these regions to be different, thus the etching rates in the different densely patterned regions may also be different, thereby affecting the etching uniformity. In the embodiments of the present disclosure, the photoresist includes charged ions, and an interaction among charges will accelerate the movement of the ions such that those consumed ions can be replenished timely and the ionic concentrations can be timely balanced. As a result, the influence caused by different etching rates can be reduced and the object of ensuring the etching uniformity can be achieved. As shown in FIG. 3, the ionic concentration in the region close to the photoresist PR is higher than that in the other regions, which indicates that the ionizable substance, i.e., chlorobenzene, in the photoresist, is ionized to generate a large number of ions under the action of UV light, which may be used for replenishing the ions that are consumed during the etching.

In the etching method as provided above in the present disclosure, the ionizable substance may be chlorobenzenes. Specifically, chlorobenzene may be ionized to generate ions under the action of UV light, and during the etching, a high pressure mercury lamp may be used for providing the UV light for the exposure of the base substrate coated with the photoresist. In this process, chlorobenzene is ionized to generate ions. When the etching is performed subsequently using an etching solution, the ions generated by the ionization of chlorobenzene can timely replenish the ions which are consumed in each region. In this way, it is able to ensure the balance of the etching rates in all of the regions and also ensure the etching uniformity of the entire substrate.

In the etching method as provided above in the present disclosure, the UV light may be provided at a wavelength of 254 nm, light intensity of 180 μW/cm², and a dose of 160 mJ/cm². At the wavelength of 254 nm, chlorobenzene has a molar extinction coefficient £254 nm of 139.6 M⁻¹ cm⁻¹, and has a high capacity of absorbing UV light. Moreover, after absorbing photons, a chlorobenzene molecule undergoes a photo chemical reaction to yield other products. The chlorobenzene molecules are excited under the irradiation of UV light, and the speed of excitation depends on the concentration and extinction coefficient of chlorobenzene at the wavelength of the UV light. The excited chlorobenzene molecule undergoes an exothermic reaction or photodecomposition to form intermediate products which may further absorb photons to become an excited intermediate and be further decomposed.

A specific ionization process of chlorobenzene under the action of UV light will be explained below.

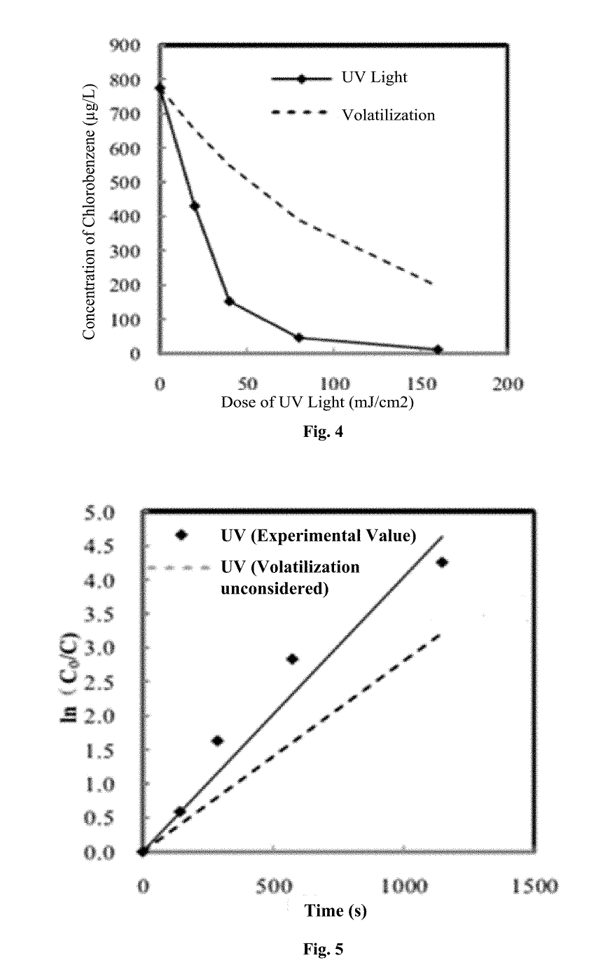

A 0.01 mM solution of chlorobenzene is prepared using ultrapure water, and UV light is provided at intensity of 180 μW/cm², and a residual concentration of chlorobenzene is measured under the irradiation of UV light with different doses. A graph of decomposition of chlorobenzene as shown in FIG. 4 is obtained. As shown in FIG. 4, when the chlorobenzene solution is in a nature state, the concentration of chlorobenzene is reduced over time, as illustrated by a dotted line in FIG. 4; under the irradiation of UV light, the decomposition rate of chlorobenzene was increased with the increase in the dose of the UV light, as illustrated by a solid line in FIG. 4. Therefore, when the photoresist including chlorobenzene is exposed to UV light, a large number of ions can be generated by ionization for replenishing the consumed ions during the etching process. Thus, a balance of the etching rates in different regions is ensured and the etching uniformity of the entire substrate is further ensured.

In addition, the chlorobenzene solution conforms to a first-order reaction rate equation ln(C₀/C)=kt. FIG. 5 shows a change in the reaction rate in the chlorobenzene solution over time with the dose of UV light of 160 mJ/cm². According to the separation of variables of the differential equation, the following equation can be obtained: dc/c=kdt, and by integrating both sides of the equation and letting t=0 and C(t=0)=C₀, we can get ln C₀−ln C=kt−0, which can be written more simply as ln(C₀/C)=kt. In addition, chlorobenzene is a highly volatile substance. A dashed line shown in FIG. 5 indicates a change in the concentration of chlorobenzene without considering volatilization, while a solid line indicates a change in the concentration of chlorobenzene under the irradiation of UV light with considering the volatilization. Although they have different slopes, both of them indicate that the concentration of chlorobenzene varies greatly under the action of UV light and the change rate increases over time. This indicates that chlorobenzene is ionized quickly to generate a large number of ions under the irradiation of UV light, that is, the effect of UV light on the decomposition of chlorobenzene is significant. Therefore, by adding chlorobenzene to the photoresist and irradiating it with UV light, a large number of ions may be generated and can be used to replenish those consumed during the etching, thereby ensuring the balance of the etching rates in different the regions and the etching uniformity of the entire substrate.

According to the embodiments of the present disclosure, the photoresist includes the ionizable substance capable of being ionized to generate ions under the irradiation of UV light. By adding such an ionizable substance to the photoresist, ions may be generated by the ionizable substance under the action of UV light during the etching. A force of attraction among electric charges accelerates the movement of the ions such that the ionic concentrations in different regions are balanced. Thus, it is able to timely replenish the ions consumed in each region on the substrate which is being etched, especially in the densely patterned region, thereby achieving the balance of the etching rates in different regions and ensuring the etching uniformity of the entire substrate.

It is obvious that a person skilled in the art may make modifications and variations to the present disclosure without departing from the spirit and scope of the present disclosure. It is intended that such medications and variations are encompassed in the present disclosure if they fall within the scope of the appended claims and equivalents thereof.

What is claimed is:

1. A photoresist comprising an ionizable substance capable of being ionized to generate ions under the irradiation of ultraviolet (UV) light.

2. The photoresist according to claim 1, wherein the ionizable substance comprises chlorobenzenes.

3. An etching method using the photoresist according to claim 1, comprising:
coating the photoresist on a film layer to be etched on a base substrate, wherein the photoresist comprises an ionizable substance capable of being ionized to generate ions under the irradiation of UV light;
exposing the base substrate coated with the photoresist to the UV light using a mask plate;
wet-etching the exposed base substrate using an etching solution; and
removing the remaining photoresist.

4. The etching method according to claim 3, wherein the ionizable substance comprises chlorobenzenes.

5. The etching method according to claim 4, further comprising providing the UV light through a high pressure mercury lamp.

6. The etching method according to claim 5, wherein the UV light is provided at a wavelength of 254 nm, light intensity of 180 μW/cm², and a dose of 160 mJ/cm².

7. The etching method according to claim 6, wherein a molar extinction coefficient of the chlorobenzenes is 139.6 M⁻¹cm⁻¹.
